(19) United States
(12) Patent Application Publication
(10) Pub. No.: US 2014/0055162 A1
(43) Pub. Date: Feb. 27, 2014

(54) ON-DIE TERMINATION CIRCUIT

(71) Applicant: SK HYNIX INC., Icheon-si (KR)

(72) Inventor: Jong Ho JUNG, Icheon-si (KR)

(73) Assignee: SK HYNIX INC., Icheon-si (KR)

(21) Appl. No.: 13/720,802

(22) Filed: Dec. 19, 2012

(30) Foreign Application Priority Data
Aug. 24, 2012 (KR) 10-2012-0093241

(51) Int. Cl. H03K 19/0175

(52) U.S. Cl. CPC H03K 19/017545
USPC 326/30

(57) ABSTRACT

An on-die termination circuit includes an impedance control unit configured to generate impedance control signals in response to an operation control signal, a driving unit configured to perform a termination function for a pad with an impedance controlled in response to the impedance control signals, and a termination control unit configured to deactivate the termination function of the driving unit in response to the operation control signal.

### CROSS-REFERENCES TO RELATED APPLICATION

The present application claims priority under 35 U.S.C. §119(a) to Korean application number 10-2012-0093241, filed on Aug. 24, 2012, in the Korean Intellectual Property Office, which is incorporated herein by reference in its entirety.

### BACKGROUND

1. Technical Field

The present invention relates generally to a semiconductor apparatus, and more particularly, to an on-die termination circuit.

2. Related Art

A semiconductor apparatus may include an on-die termination circuit for performing a termination operation to match the impedance of a terminal such as an input/output pad, to a desired value.

### SUMMARY

An on-die termination circuit which can improve the performance of a read operation is described herein.

In an embodiment, an on-die termination circuit includes: an impedance control unit configured to generate impedance control signals in response to an operation control signal; a driving unit configured to perform a termination function for a pad with an impedance controlled in response to the impedance control signals; and a termination control unit configured to deactivate the termination function of the driving unit in response to the operation control signal.

In another embodiment, an on-die termination circuit includes: an impedance control unit configured to generate impedance control signals in response to an operation control signal; a driving unit configured to perform a termination function for a first pad and a second pad with an impedance controlled in response to the impedance control signals; and a termination control unit configured to deactivate the termination function of the driving unit in response to the operation control signal.

### BRIEF DESCRIPTION OF THE DRAWINGS

Features, aspects, and embodiments are described in conjunction with the attached drawings, in which:

FIG. 1 is a block diagram showing the configuration of an on-die termination circuit in accordance with an embodiment;

FIG. 2 is a timing diagram showing a termination operation according to FIG. 1;

FIG. 3 is a timing diagram illustrating a termination disable period according to another embodiment;

FIG. 4 is a block diagram showing the configuration of an on-die termination circuit in accordance with another embodiment;

FIG. 5 is a circuit diagram showing the configuration of the termination control unit of FIG. 4;

FIG. 6 is a circuit diagram of the driving unit of FIG. 4; and

FIG. 7 is a timing diagram showing a termination operation according to FIG. 4.

### DETAILED DESCRIPTION

Hereinafter, an on-die termination circuit according to the present invention will be described below with reference to the accompanying drawings through various embodiments.

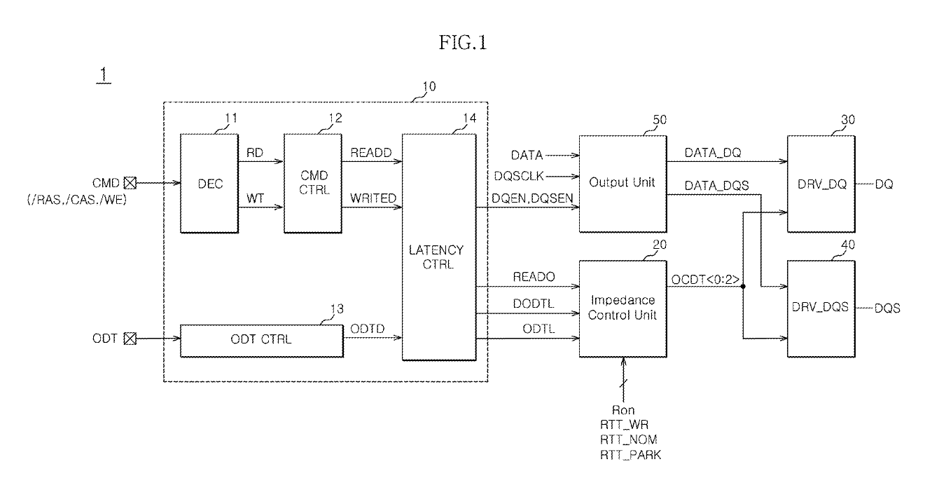

Referring to FIG. 1, an on-die termination circuit 1 in accordance with an embodiment includes a timing control unit 10, an impedance control unit 20, an output unit 50, a first driving unit 30, and a second driving unit 40.

The timing control unit 10 is configured to respond to a first command CMD and a second command ODT, that is, to control the timing of the first command CMD and the second command ODT, and to generate a plurality of operation control signals READO, DODTL and ODTL and enable signals DQEN and DQSEN.

The first command CMD includes a read command RD and a write command WT as combinations of /RAS, /CAS, and /WE.

The second command ODT may be an on-die termination command.

The timing control unit 10 includes a decoder (DEC) 11 and timing control blocks (CMD CTRL, ODT CTRL and LATENCY CTRL) 12, 13, and 14, respectively.

The decoder 11 is configured to decode the first command CMD and generate the read command RD and the write command WT.

The timing control block (CMD CTRL) 12 is configured to delay the read command RD and the write command WT to conform to a predetermined time standard, and generate delayed signals READD and WRITED.

The timing control block (ODT CTRL) 13 is configured to delay the second command ODT to conform to the predetermined time standard, and generate a delayed signal ODTD.

The timing control block (LATENCY CTRL) 14 is configured to shift the delayed signals READD, WRITED, and ODTD by the predetermined time standard on the basis of a clock signal, and generate the plurality of operation control signals READO, DODTL, and ODTL and enable signals DQEN and DQSEN.

READO is the operation control signal associated with a read command, DODTL is the operation control signal associated with a dynamic on-die termination command, and ODTL is the operation control signal associated with an on-die termination command.

DODTL is an operation control signal for implementing on-die termination in a write operation.

The enable signal DQEN is the signal associated with output control of data DATA.

The enable signal DQSEN is the signal associated with output control of a clock signal DQSCLK.

The impedance control unit 20 is configured to generate impedance control signals OCDT<0:2> corresponding to impedance setting values Ron, RTT_WR, RTT_NOM, and RTT_PARK, in response to the operation control signals READO, DODTL, and ODTL.

The impedance control unit 20 generates the impedance control signals OCDT<0:2> corresponding to the impedance setting value RTT_PARK when any one of the operation control signals READO, DODTL and ODTL is not activated.

The impedance control unit 20 generates the impedance control signals OCDT<0:2> corresponding to the impedance setting value RTT_NOM when the operation control signal ODTL among the operation control signals READO, DODTL, and ODTL is activated.

The impedance control unit 20 generates the impedance control signals OCDT<0:2> corresponding to the impedance setting value RTT_WR when the operation control signal DODTL among the operation control signals READO, DODTL, and ODTL is activated.

The impedance control unit 20 generates the impedance control signals OCDT<0:2> corresponding to the impedance setting value Ron when the operation control signal READO among the operation control signals READO, DODTL, and ODTL is activated.

The output unit 50 is configured to output the data DATA and the clock signal DQSCLK in response to the respective enable signals DQEN and DQSEN.

The output unit 50 outputs the data DATA when the enable signal DQEN is activated.

The output unit 50 outputs the clock signal DQSCLK when the enable signal DQSEN is activated.

The first driving unit (DRV_DQ) 30 is configured to drive or terminate a pad DQ with a controlled impedance in response to an output signal DATA_DQ of the output unit 50 and the impedance control signals OCDT<0:2>.

The second driving unit (DRV_DQS) 40 is configured to drive or terminate a pad DQS with a controlled impedance in response to an output signal DATA_DQS of the output unit 50 and the impedance control signals OCDT<0:2>.

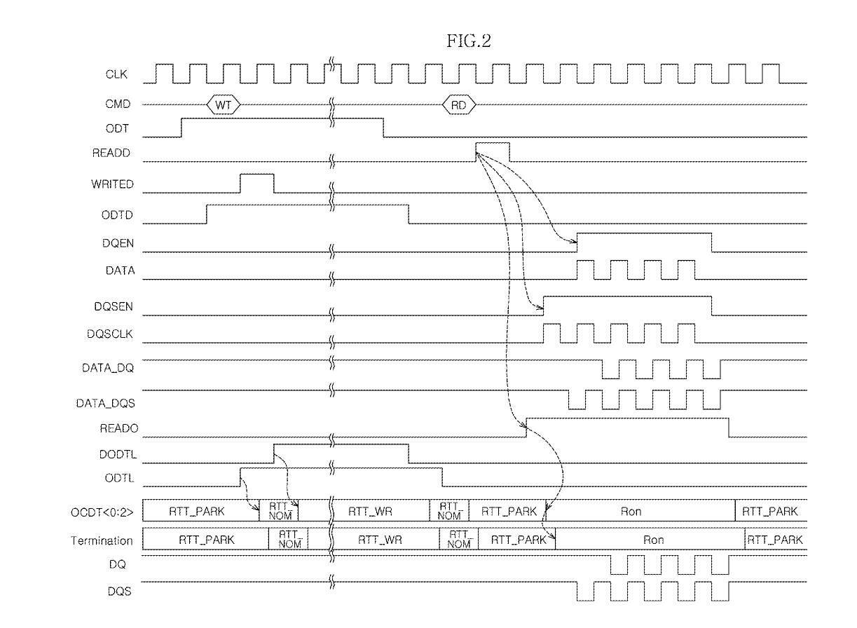

The termination operations of the on-die termination circuit 1 in accordance with the embodiment will be described below with reference to FIG. 2.

The impedance control unit 20 generates the impedance control signals OCDT<0:2> corresponding to the impedance setting value RTT_PARK when any one of the operation control signals READO, DODTL and ODTL is not activated, as mentioned above.

Accordingly, the pad DQ/DQS is terminated and corresponds with the impedance setting value RTT_PARK.

When a predetermined time lapses after the on-die termination command ODT is inputted, the operation control signal ODTL is activated.

As the operation control signal ODTL is activated, the impedance control unit 20 generates the impedance control signals OCDT<0:2> corresponding to the impedance setting value RTT_NOM.

Accordingly, the pad DQ/DQS is terminated and corresponds with the impedance setting value RTT_NOM.

When the write command WT is inputted within the activation period of the on-die termination command ODT, the operation control signal DODTL is activated after the lapse of a predetermined time.

As the operation control signal DODTL is activated, the impedance control unit 20 generates the impedance control signals OCDT<0:2> corresponding to the impedance setting value RTT_WR.

Accordingly, the pad DQ/DQS is terminated and corresponds with the impedance setting value RTT_WR.

When the read command RD is inputted, the operation control signal READO is activated after the lapse of a predetermined time.

As the operation control signal READO is activated, the is impedance control unit 20 generates the impedance control signals OCDT<0:2> corresponding to the impedance setting value Ron.

Accordingly, data output is implemented with the pad DQ/DQS set with the impedance setting value Ron.

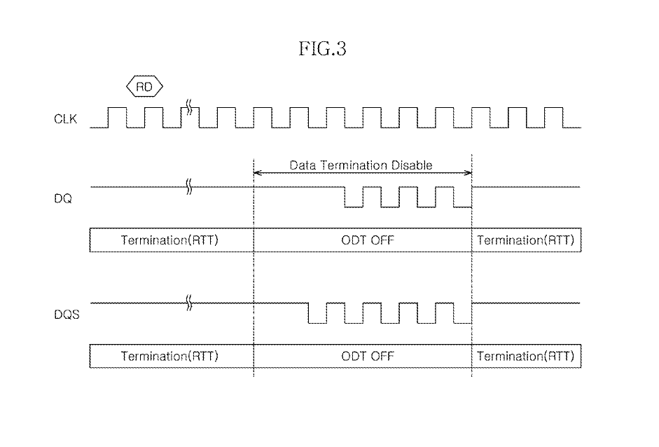

Another embodiment has a termination disable period during a period in which a read operation, that is, data output, is actually performed, after a predetermined standard time following the read command RD input, as shown in FIG. 3, in order to improve the performance of the read operation.

Referring to FIG. 3, termination is implemented with the determined impedance RTT_PARK, RTT_NOM or RTT_WR during periods except for when the read operation according to the read command RD is performed.

During the period in which the read operation is performed, the on-die termination function is deactivated (ODT OFF).

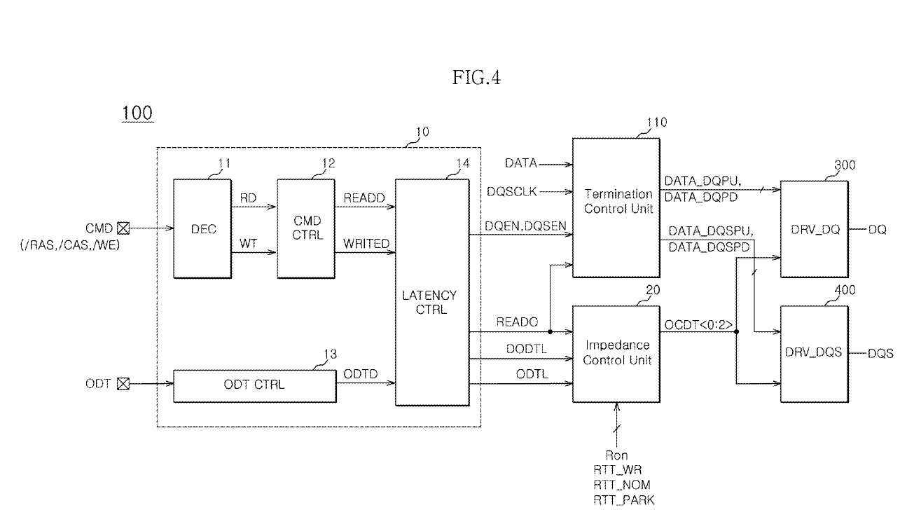

Referring to FIG. 4, an on-die termination circuit 100 in accordance with another embodiment includes a timing control unit 10, an impedance control unit 20, a termination control unit 110, a first driving unit 300, and a second driving unit 400.

The timing control unit 10 is configured to respond to a first command CMD and a second command ODT, that is, to control the timing of the first command CMD and the second command ODT, and to generate a plurality of operation control signals READO, DODTL and ODTL and enable signals DQEN and DQSEN.

The first command CMD includes a read command RD and a write command WT as combinations of /RAS, /CAS, and /WE.

The second command ODT may be an on-die termination command.

The timing control unit 10 includes a decoder (DEC) 11 and timing control blocks (CMD CTRL, ODT CTRL and LATENCY CTRL) 12, 13, and 14, respectively.

The decoder 11 is configured to decode the first command CMD and generate the read command RD and the write command WT.

The timing control block (CMD CTRL) 12 is configured to delay the read command RD and the write command WT to conform to a predetermined time standard, and generate delayed signals READD and WRITED.

The timing control block (ODT CTRL) 13 is configured to delay the second command ODT to conform to the predetermined time standard, and generate a delayed signal ODTD.

The timing control block (LATENCY CTRL) 14 is configured to shift the delayed signals READD, WRITED, and ODTD by the predetermined time standard on the basis of a clock signal, and generate the plurality of operation control signals READO, DODTL, and ODTL and enable signals DQEN and DQSEN.

READO is the operation control signal associated with a read command, DODTL is the operation control signal associated with a dynamic on-die termination command, and ODTL is the operation control signal associated with an on-die termination command.

DODTL is an operation control signal for implementing on-die termination in a write operation.

The impedance control unit 20 is configured to generate impedance control signals OCDT<0:2> corresponding to impedance setting values Ron, RTT_WR, RTT_NOM, and RTT_PARK, in response to the operation control signals READO, DODTL, and ODTL.

The impedance control unit 20 generates the impedance control signals OCDT<0:2> corresponding to the impedance setting value RTT_PARK when even any one of the operation control signals READO, DODTL and ODTL is not activated.

The impedance control unit 20 generates the impedance control signals OCDT<0:2> corresponding to the impedance setting value RTT_NOM when the operation control signal ODTL among the operation control signals READO, DODTL and ODTL is activated.

The impedance control unit 20 generates the impedance control signals OCDT<0:2> corresponding to the impedance setting value RTT_WR when the operation control signal DODTL among the operation control signals READO, DODTL and ODTL is activated.

The impedance control unit 20 generates the impedance control signals OCDT<0:2> corresponding to the impedance setting value Ron when the operation control signal READO among the operation control signals READO, DODTL and ODTL is activated.

The first driving unit (DRV_DQ) 300 is configured to have impedance controlled in response to the impedance control signals OCDT<0:2> and perform a termination function for a pad DQ in response to activation of first driving signals DATA_DQPU and DATA_DQPD.

The second driving unit (DRV_DQS) 400 is configured to have impedance controlled in response to the impedance control signals OCDT<0:2> and perform a termination function for a pad DQS in response to activation of second driving signals DATA_DQSPU and DATA_DQSPD.

The termination control unit 110 is configured to recognize a read operation and deactivate the on-die termination function of the first driving unit 300 and the second driving unit 400.

The termination control unit 110 is configured to generate the first driving signals DATA_DQPU and DATA_DQPD and the second driving signals DATA_DQSPU and DATA_DQSPD in response to data DATA, a clock signal DQSCLK, the enable signals DQEN and DQSEN, and the operation control signal READO.

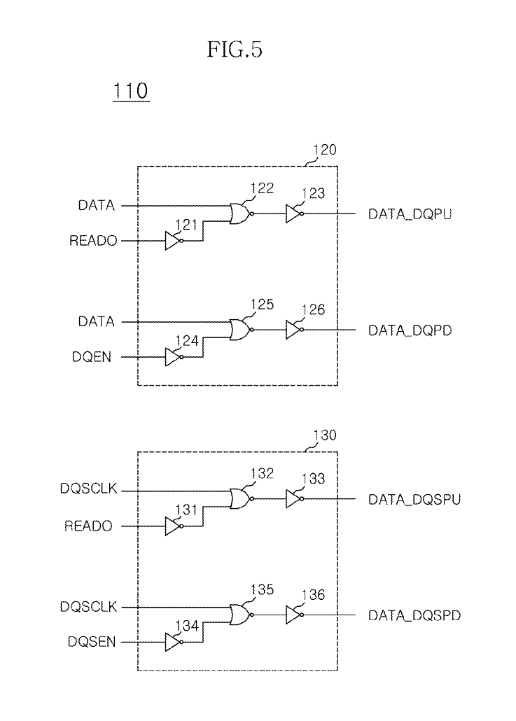

Referring to FIG. 5, the termination control unit 110 includes a first control section 120 and a second control section 130.

The first control section 120 is configured to generate the first driving signals DATA_DQPU and DATA_DQPD in response to the data DATA, the enable signal DQEN, and the operation control signal READO.

The first control section 120 is configured to NOR the data DATA and the inverted signal of the operation control signal READO, and generate the first driving signal DATA_DQPU.

The first control section 120 outputs the data DATA as the first driving signal DATA_DQPU when the operation control signal READO is activated, and outputs the first driving signal DATA_DQPU at a high level regardless of the level of the data DATA when the operation control signal READO is deactivated.

The first control section 120 is configured to NOR the data DATA and the inverted signal of the enable signal DQEN, and generate the first driving signal DATA_DQPD.

The first control section 120 outputs the data DATA as the first driving signal DATA_DQPD when the enable signal DQEN is activated, and outputs the first driving signal DATA_DQPD at a high level regardless of the level of the data DATA when the enable signal DQEN is deactivated.

The first control section 120 comprises a plurality of inverters 121, 123, 124 and 126 and a plurality of NOR gates 122 and 125.

The second control section 130 is configured to generate the second driving signals DATA_DQSPU and DATA_DQSPD in response to the clock signal DQSCLK, the enable signal DQSEN and the operation control signal READO.

The second control section 130 is configured to NOR the clock signal DQSCLK and the inverted signal of the operation control signal READO, and generate the second driving signal DATA_DQSPU.

The second control section 130 outputs the clock signal DQSCLK as the second driving signal DATA_DQSPU when the operation control signal READO is activated, and outputs the second driving signal DATA_DQSPU at a high level regardless of the level of the clock signal DQSCLK when the operation control signal READO is deactivated.

The second control section 130 is configured to NOR the clock signal DQSCLK and the inverted signal of the enable signal DQSEN, and generate the second driving signal DATA_DQSPD.

The second control section 130 outputs the clock signal DQSCLK as the second driving signal DATA_DQSPD when the enable signal DQSEN is activated, and outputs the second driving signal DATA_DQSPD at a high level regardless of the level of the clock signal DQSCLK when the enable signal DQSEN is deactivated.

The second control section 130 comprises a plurality of inverters 131, 133, 134 and 136 and a plurality of NOR gates 132 and 135.

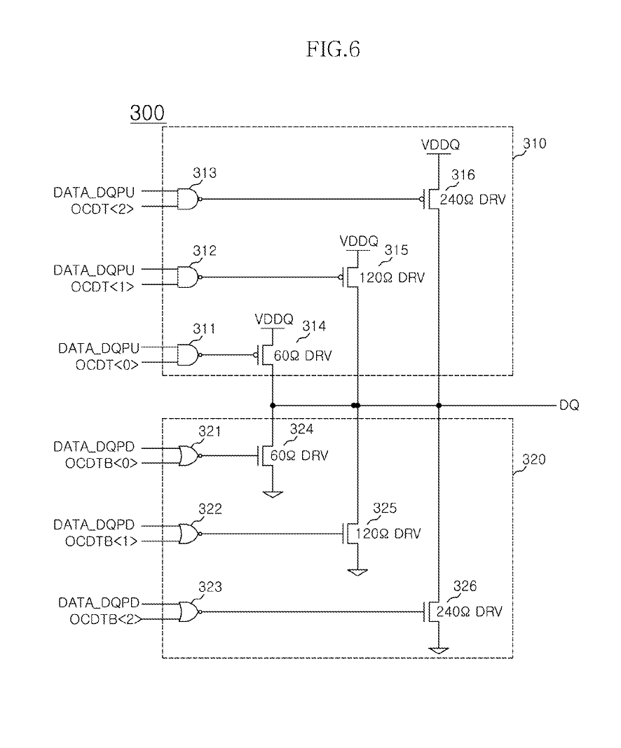

Referring to FIG. 6, the first driving unit 300 includes a pull-up driving section 310 and a pull-down driving section 320.

The pull-up driving section 310 comprises a plurality of NAND gates 311 to 313 and a plurality of drivers 314 to 316 which have different resistance values.

The pull-down driving section 320 comprises a plurality of NOR gates 321 to 323 and a plurality of drivers 324 to 326 which have different resistance values.

The output terminals, that is, the drain terminals, of the plurality of drivers 314 to 316 and 324 to 326 are commonly connected to the pad DQ.

The first driving unit 300 deactivates the plurality of drivers 314 to 316 when the first driving signal DATA_DQPU has a low level, and thus, deactivates the on-die termination function (ODT OFF).

The first driving unit 300 deactivates the plurality of drivers 324 to 326 when the first driving signal DATA_DQPD has a high level.

The second driving unit 400 may be configured in a substantially similar manner as the first driving unit 300.

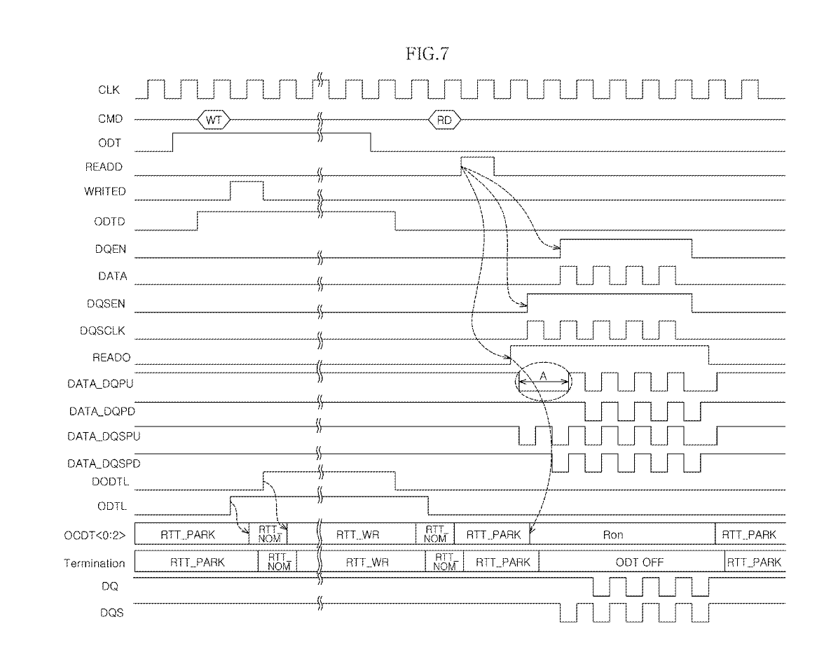

The termination operations of the on-die termination circuit 100 in accordance with another embodiment will be described below with reference to FIG. 7.

The impedance control unit 20 generates the impedance control signals OCDT<0:2> corresponding to the impedance setting value RTT_PARK when any one of the operation control signals READO, DODTL and ODTL is not activated as mentioned above.

Since all of the enable signals DQEN and DQSEN and the operation control signal READO are in states deactivated to low levels, the termination control unit 110 outputs all the first driving signals DATA_DQPU and DATA_DQPD and the second driving signals DATA_DQSPU and DATA_DQSPD at high levels.

Since all of the first driving signals DATA_DQPU and DATA_DQPD have high levels, all of the plurality of drivers 324 to 326 of the first driving unit 300 are deactivated, and some drivers of the plurality of drivers 314 to 316, corresponding to the impedance control signals OCDT<0:2>, are activated.

As some drivers of the plurality of drivers 314 to 316 of the first driving unit 300 are activated, the pad DQ is terminated with the impedance setting value RTT_PARK.

The second driving unit 400 operates in the same manner as the first driving unit 300, and the pad DQS is terminated and corresponds with the impedance setting value RTT_PARK.

When the predetermined time lapses after the on-die termination command ODT is inputted, the operation control signal ODTL is activated.

As the operation control signal ODTL is activated, the impedance control unit 20 generates the impedance control signals OCDT<0:2> corresponding to the impedance setting value RTT_NOM.

Since all of the enable signals DQEN and DQSEN and the operation control signal READO are in states deactivated to low levels, the termination control unit 110 outputs all the first driving signals DATA_DQPU and DATA_DQPD and the second driving signals DATA_DQSPU and DATA_DQSPD at high levels.

Since all of the first driving signals DATA_DQPU and DATA_DQPD have high levels, all of the plurality of drivers 324 to 326 of the first driving unit 300 are deactivated, and some drivers of the plurality of drivers 314 to 316, corresponding to the impedance control signals OCDT<0:2>, are activated.

As some drivers of the plurality of drivers 314 to 316 of the first driving unit 300 are activated, the pad DQ is terminated and corresponds with the impedance setting value RTT_NOM.

The second driving unit 400 operates in a substantially similar manner as the first driving unit 300, and the pad DQS is terminated and corresponds with the impedance setting value RTT_NOM.

When the write command WT is inputted within the activation period of the on-die termination command ODT, the operation control signal DODTL is activated after the lapse of the predetermined time.

As the operation control signal DODTL is activated, the impedance control unit 20 generates the impedance control signals OCDT<0:2> corresponding to the impedance setting value RTT_WR.

Since all of the enable signals DQEN and DQSEN and the operation control signal READO are in states deactivated to low levels, the termination control unit 110 outputs all the first driving signals DATA_DQPU and DATA_DQPD and the second driving signals DATA_DQSPU and DATA_DQSPD at high levels.

Since all of the first driving signals DATA_DQPU and DATA_DQPD have high levels, all of the plurality of drivers 324 to 326 of the first driving unit 300 are deactivated, and some drivers of the plurality of drivers 314 to 316, corresponding to the impedance control signals OCDT<0:2>, are activated.

As some drivers of the plurality of drivers 314 to 316 of the first driving unit 300 are activated, the pad DQ is terminated and corresponds with the impedance setting value RTT_WR.

The second driving unit 400 operates in a substantially similar manner as the first driving unit 300, and the pad DQS is terminated and corresponds with the impedance setting value RTT_WR.

If the read command RD is inputted, the operation control signal READO, the enable signal DQSEN, and the enable signal DQEN are sequentially activated after the lapse of the predetermined time.

As the operation control signal READO is activated, the impedance control unit 20 generates the impedance control signals OCDT<0:2> corresponding to the impedance setting value Ron.

From the time at which the enable signal DQEN is activated, the output of the data DATA, that is, the transition of the data DATA, is implemented.

In other words, the data DATA is retained at a low level from the time at which the operation control signal READO is activated to the time at which the enable signal DQEN is activated.

The termination control unit 110 outputs the first driving signals DATA_DQPU and DATA_DQPD at a low level and a high level, respectively, during the time in which the enable signal DQEN is deactivated and the data DATA retains a low level.

Since the first driving signals DATA_DQPU and DATA_DQPD have a low level and a high level, respectively, all of the plurality of drivers 314 to 316 and 324 to 326 of the first driving unit 300 are deactivated.

As all of the plurality of drivers 314 to 316 and 324 to 326 are deactivated, the on-die termination function is deactivated (ODT OFF) as in the period “A”.

Then, the read operation is performed in response to the sequential activation of the enable signal DQSEN and the enable signal DQEN.

Namely, as the enable signal DQSEN is activated, the second driving unit 400 outputs the clock signal through the pad DQS, and as the enable signal DQEN is activated, the first driving unit 300 outputs the data through the pad DQ.

In embodiments, the performance of the read operation may be improved through the control of the termination function.

While certain embodiments have been described above, it will be understood to those skilled in the art that the embodiments described are by way of example only. Accordingly, the on-die termination circuit described herein should not be limited based on the described embodiments. Rather, the on-die termination circuit described herein should only be limited in light of the claims that follow when taken in conjunction with the above description and accompanying drawings.

What is claimed is:

1. An on-die termination circuit comprising:
an impedance control unit configured to generate impedance control signals in response to an operation control signal;
a driving unit configured to perform a termination function for a pad with an impedance controlled in response to the impedance control signals; and
a termination control unit configured to deactivate the termination function of the driving unit in response to the operation control signal.

2. The on-die termination circuit according to claim 1, wherein the operation control signals are generated in response to a is read command.

3. The on-die termination circuit according to claim 1, wherein the impedance control unit is configured to change a value of the impedance control signals in response to a plurality of operation control signals including the operation control signal and a plurality of impedance setting values.

4. The on-die termination circuit according to claim 1, further comprising:
a timing control unit configured to generate the plurality of operation control signals including the operation control signal in response to the read command, a write command, and an on-die termination command.

5. The on-die termination circuit according to claim 1, wherein the driving unit is configured to have impedance controlled in response to the impedance control signals and perform the termination function for the pad in response to driving signals.

6. The on-die termination circuit according to claim 5, wherein the termination control unit is configured to generate the driving signals in response to data and the operation control signal.

7. An on-die termination circuit comprising:
is an impedance control unit configured to generate impedance control signals in response to an operation control signal;
a driving unit configured to perform a termination function for a first pad and a second pad with an impedance controlled in response to the impedance control signals; and
a termination control unit configured to deactivate the termination function of the driving unit in response to the operation control signal.

8. The on-die termination circuit according to claim 7, wherein the operation control signals are generated in response to a read command.

9. The on-die termination circuit according to claim 7, wherein the impedance control unit is configured to change a value of the impedance control signals in response to a plurality of operation control signals including the operation control signal and a plurality of impedance setting values.

10. The on-die termination circuit according to claim 7, further comprising:
a timing control unit configured to generate the plurality of operation control signals including the operation control signal in response to the read command, a write command, and an on-die termination command.

11. The on-die termination circuit according to claim 7, wherein the driving unit comprises:
a first driving unit configured to have impedance controlled in response to the impedance control signals and perform the termination function for the first pad in response to first driving signals; and
a second driving unit configured to have impedance controlled in response to the impedance control signals and perform the termination function for the second pad in response to second driving signals.

12. The on-die termination circuit according to claim 11, wherein the termination control unit comprises:
a first control section configured to generate the first driving signals in response to data and the operation control signal; and
a second control section configured to generate the second driving signals in response to a clock signal and the operation control signal.

13. The on-die termination circuit according to claim 7, further comprising:
a timing control unit configured to generate the plurality of operation control signals including the operation control signal, a first enable signal and a second enable signal in response to the read command, a write command, and an on-die termination command.

14. The on-die termination circuit according to claim 13, wherein the timing control unit further comprising:
a decoder configured to decode the read command;
a first timing control block configured to delay the output of the decoder to conform to a predetermined time standard;
a second timing control block configured to delay the one-die termination command to conform to the predetermined time standard; and
a third timing control block configured to shift the outputs of the first timing control block and the second timing control block by the predetermined time standard on the basis of a clock signal.

15. The on-die termination circuit according to claim 13, wherein the driving unit comprises:
a first driving unit configured to have impedance controlled in response to the impedance control signals and perform the termination function for the first pad in response to first driving signals; and
a second driving unit configured to have impedance controlled in response to the impedance control signals and perform the termination function for the second pad in response to second driving signals.

16. The on-die termination circuit according to claim 15, wherein the termination control unit comprises:
a first control section configured to generate the first driving signals in response to data, the first enable signal, and the operation control signal; and
a second control section configured to generate the second driving signals in response to a clock signal, the second enable signal, and the operation control signal.
